(19) United States
(12) Patent Application Publication
(10) Pub. No.: US 2022/0341987 A1
(43) Pub. Date: Oct. 27, 2022

(54) Test Device and Method for Roll-to-Roll Board of Flexible Circuit Board

(71) Applicant: Xiamen University of Technology, Xiamen (CN)

(72) Inventors: An Xie, Xiamen (CN); Dongya Sun, Xiamen (CN); Chunyan Cao, Xiamen (CN); Yuechan Li, Xiamen (CN); Xiangjun Lu, Xiamen (CN); Liang Yang, Xiamen (CN)

(21) Appl. No.: 17/542,543

(22) Filed: Dec. 6, 2021

(30) Foreign Application Priority Data
Apr. 26, 2021 (CN) 202110458490.X

(51) Int. Cl. G01R 31/28; H05K 1/02

(52) U.S. Cl. CPC G01R 31/2808; H05K 1/0268

(57) ABSTRACT

Provided is a test device for roll-to-roll board of flexible circuit boards. The test device comprises a detection probe frame, front and rear ends of the detection probe frame being connected to a sliding frame, and a bottom of the sliding frame being connected to a magnetic plate; wherein the magnetic plate is consisted of a square panel in the middle and four isosceles trapezoidal panels in upright direction; the four isosceles trapezoidal panels is movable and is capable of being rotated towards the square panel; a bottom of the square panel is provided with 4×4 centralized ports, the angle between the centralized port and a vertical line of the panel is 30°; the upper surface of the magnetic plate is provided with four catching splints, the catching splint is movable on the magnetic plate.

### CROSS REFERENCE OF RELATED APPLICATIONS

The present disclosure claims the benefit of Chinese Patent Application No. 202110458490.X entitled “Test Device and Method for Roll-to-Roll Board of Flexible Circuit Board,” filed on Apr. 26, 2021, in the China National Intellectual Property Administration, the entire content of which is incorporated herein in its entirety.

### TECHNICAL FIELD

The present disclosure relates to a technical filed of flexible circuit board manufacturing equipment, in particular to testing device and method of roll-to-roll boards.

### BACKGROUND

The difference between flexible circuit boards and traditional PCB circuit board is that the flexible circuit board is light-weight, flexible, and does not require additional wiring time. It needs to be inspected after the preparation is completed. Most of the current inspection methods used are through visual inspection. However, as the complexity of circuit boards increases, inspection of the surface alone cannot meet the needs of most companies today.

Based on the above description, the inventor found that the existing flexible circuit board roll-to-roll board testing device and method mainly have the following shortcomings, for example:

1. when fixing the circuit board, the prior art only fixes the circuit board on a flat surface. However, because the flexible circuit board has a certain degree of foldability, it is difficult to ensure that each surface is in a horizontal state when inspecting it, which is extremely easy Because it is not spread out, the detection position is not accurate, and it is easy to miss the short-circuit and open-circuit points.

2. the flexible circuit board needs to be fixed in a fixed position during inspection by the inspector, and the fixed position needs to be accurate, which is a waste of time.

3. in the prior art, when a defective pixel on the circuit board is detected, there is no way to correct it to eliminate the deviation, and it can only simply detect the defective pixel.

### SUMMARY

In order to solve the above technical problems, the present disclosure provides a flexible circuit board roll-to-roll board testing device and method to solve the existing problems.

The present disclosure is achieved by a test device and a method for roll-to-roll board of flexible circuit boards. The test device comprises a detection probe frame, front and rear ends of the detection probe frame being connected to a sliding frame, and a bottom of the sliding frame being connected to a magnetic plate; wherein the magnetic plate is consisted of a square panel in the middle and four isosceles trapezoidal panels in upright direction; the four isosceles trapezoidal panels is movable and is capable of being rotated towards the square panel; a bottom of the square panel is provided with 4×4 centralized ports, the angle between the centralized port and a vertical line of the panel is 30°; the upper surface of the magnetic plate is provided with four catching splints, the catching splint is movable on the magnetic plate, and there is a magnetic relationship between the catching splint and the magnetic plate; a pulling force of the catching splint is 50 N-980 N; the catching splint comprises a buckle frame; the buckle frame is welded with two side lifting plates; a bottom of the side lifting plate is a right-angled triangle with an apex angle of 15°, and a square slot is connected to the side lifting plate. A depth of the square slot is 5 cm; a top of the square slot is a right-angle trapezoid; one side of an oblique side of side lifting plate faces outward and a vertical positioning pin is connected inside.

In some embodiments, inner side nails of the two side lifting plates are connected to corner fixing clips; a section of the corner fixing clip facing the outside is arc-shaped.

In some embodiments, the corner fixing clip comprises a clamping concave plate connected between the two side lifting plates; an inner center of the clamping concave plate is connected to an electromagnetic wheel. The electromagnetic wheel is magnetic, and a supercharger is located within the electromagnetic; increasing the overall voltage in the case of constant resistance, the current is increased and, therefore, the magnetic force of the electromagnetic wheel is increased.

In some embodiments, an inner side of one end of the arc edge of the clamping concave plate is also connected to a corner piece; the inner side of the corner piece has an occlusal head, the occlusal head is an equilateral triangle structure, one of the vertices being used as the fulcrum, and the other two vertices being used as the fulcrum to contact the circuit board.

In some embodiments, the detection probe comprises a clamping portion connected therein; a probe is movably connected to a bottom of the clamping portion, and a movable angle of the top of the probe in the clamping portion is −30° to 30°; a bottom part of the probe is a triangular body, and three downward faces of the probe are all connected with friction hair balls; the friction hair balls are round colloids and have certain flexibility; the top of the clamping portion also comprises an indicator light electrically connected to the probe; the indicator light turns green when the indicator light is energized and transmits current; the indicator light turns gray when the indicator light loses power; the indicator light turns red when the indicator light contacts the circuit and there is no current.

In some embodiments, the density of the probes distributed on the lower surface of the detection probe is 18×11; a total of 198 probes cover all the points on the flexible circuit board; the probes correspond to the number and positions of the clamping portion and the indicator light one by one.

In some embodiments, the clamping portion comprises a clamping cavity connected therein; an upper left corner and an upper right corner of the clamping cavity are respectively connected with a disassembly adjusting arm; the disassembly adjusting arm is capable of being rotated 30° left and right with the inner vertex as the axis, so the left and right ends of the inner side of the clamping cavity also comprise two sets of oscillating heads; the oscillating heads have an oscillator inside which can be controlled to perform periodic reciprocating movements; the disassembly adjusting arm is capable of opening the clamping cavity.

A test method for the test device as described above comprises the following steps:

S1: transmission: providing a processed flexible circuit board without components soldered thereon onto a magnetic board, no need to specify the position, the magnetic board attracts the flexible circuit board to a middle square panel, and central ports in the square panel allows the flexible circuit board to move to the middle position.

S2: positioning: moving the electromagnetic wheel to four corners of the flexible circuit board; if a pattern of the circuit board has multiple branches, a wire board is divided into multiple tests; the lifting board clamps the two sides, and the corner piece clamps the top corner and allows the electromagnetic wheel to expand outward, so that the flexible circuit board is tightened;

S3: judgment: moving the probe down to the copper foil of the flexible circuit board; at this time, the normal copper foil point is formed with the probe and the indicator light; when the circuit is turned on, the indicator light will light up; when the abnormal copper foil is in contact with the probe and the indicator light, the indicator light; no normal current is received, but the pressure signal feedback of the probe touching the copper foil is obtained, and the red fault light is lit up immediately, which is the fault point;

S4: correction: for the location of the fault point, activating the oscillating head to periodically impact the probe, so that the friction hair ball at the bottom of the probe; rubbing the circuit on the copper foil, wipe away the excess oxidation and possible contamination of foreign objects, and stimulating the circuit to make it through the test as much as possible.

S5: marking: when all the indicator lights in a flexible circuit board are all lit green, the entire circuit is on, and the marking mechanism in the detection probe is activated to mark the detection probe; the marked flexible circuit board is a qualified circuit board, and the rest without being marked are unqualified.

The disclosure provides a flexible circuit board roll-to-roll board testing device and method, which has reasonable design and strong functionality, and has the following advantages.

1. When the flexible circuit board reaches the approximate position, use the electromagnetic wheel to move the side pick-up board to fix the three points of one corner of the flexible circuit board, fix the four corners and pull out to make the flexible circuit board It is completely spread out, without any wrinkles and dead corners, it is convenient for the probe to test each circuit line, reducing the existence of short-circuit points and disconnection points.

2. The staff only needs to place the flexible circuit board at any position on the magnetic board. The trapezoidal panels on all sides will rotate along the contact position with the square panel, move the circuit board to the middle position, and move to the square panel in the middle. The airflow ejected by the concentrated hole rushes to the middle, making it in the middle of the magnetic plate, saving the staff time to place it in the middle every time, and has a strong self-positioning ability.

3. When the conduction signal is not detected, the probe will move in the clamping cavity, so that the friction hair ball at the bottom continuously cleans the corresponding points on the circuit board, removes the interference on the top, and corrects the circuit. Dead pixels, reduce or even eliminate external influence factors, so that the circuit can be turned on, and improve the pass rate of the flexible circuit board.

### BRIEF DESCRIPTION OF THE DRAWINGS

In order to explain the technical solutions of the embodiments of the present disclosure more clearly, the following will briefly introduce the drawings that need to be used in the embodiments. It should be understood that the following drawings only show certain embodiments of the present disclosure, and therefore do not It should be regarded as a limitation of the scope. For those of ordinary skill in the art, without creative work, other related drawings can be obtained based on these drawings.

FIG. 1 is a schematic diagram of a test device for roll-to-roll of flexible circuit boards according to embodiments of the present disclosure.

FIG. 2 is a schematic diagram of a catching splints according to embodiments of the present disclosure.

FIG. 3 is a schematic diagram of a detection probe frame from top view according to embodiments of the present disclosure.

FIG. 4 is a schematic diagram of the detection probe frame from bottom view according to embodiments of the present disclosure.

FIG. 5 is a schematic diagram of the detection probe frame in operation from right side according to embodiments of the present disclosure.

FIG. 6 is a schematic diagram of the inside of the detection probe frame according to embodiments of the present disclosure.

In the drawings: detection probe frame—20; sliding frame—21; catching splint—22; magnetic plate—23; side lifting plate—220; buckle frame—221, corner fixing clip—222, clamping concave plate—200, corner piece—300, electromagnetic wheel—400, indicator light—50, clamping portion—51, probe—52, clamping cavity—510, disassembly adjusting arm—511, oscillation head—512.

### DETAILED DESCRIPTION OF THE EMBODIMENTS

In order to make the objectives, technical solutions, and advantages of the embodiments of the present disclosure clearer, the technical solutions in the embodiments of the present disclosure will be described clearly and completely in conjunction with the accompanying drawings in the embodiments of the present disclosure. Obviously, the described embodiments It is a part of the embodiments of the present disclosure, but not all of the embodiments. Therefore, the following detailed description of the embodiments of the present disclosure provided in the accompanying drawings is not intended to limit the scope of the claimed disclosure, but merely represents selected embodiments of the present disclosure. Based on the embodiments of the present disclosure, all other embodiments obtained by those of ordinary skill in the art without creative work shall fall within the protection scope of the present disclosure.

### First Embodiment

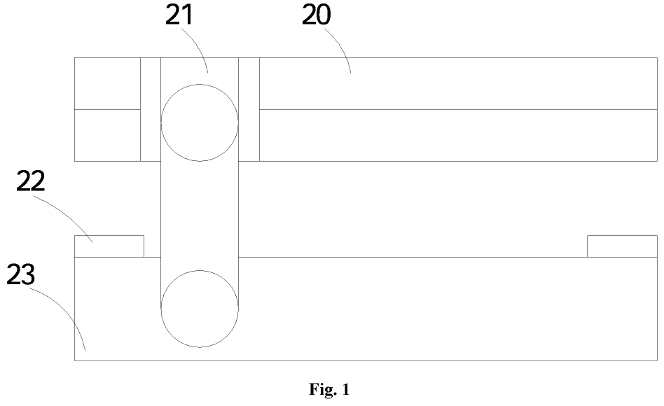

As shown in FIG. 1, the present disclosure provides a test device for roll-to-roll of flexible circuit boards. The test device comprises a detection probe frame 20. The front and rear ends of the detection probe frame 20 are connected with a sliding frame 21. The bottom of the sliding frame 21 is connected with a magnetic plate 23. The magnetic plate 23 has a square panel in the middle and four isosceles trapezoid panels in the upright direction. The four isosceles trapezoid panels are movable and can face the square panel. The bottom of the square panel is provided with 4×4 concentration openings, and the angle between the concentration opening and the vertical line of the panel is 30°. The upper surface of the magnetic plate 23 is provided with four capturing splints 22, so the catching splint 22 can be moved arbitrarily on the magnetic plate 23, and there is a magnetic relationship between the two. The pulling force of the catching splint 22 is 50 N-980 N, and the catching splint 22 includes a buckle frame 221. The frame 221 is also welded with two side lifting plates 220. The bottom of the side lifting plates 220 is a right-angled triangle with an apex angle of 15°, and a square card slot is connected to the top of it. The depth is 5 cm, the top of the square card slot is a right-angled trapezoid, one side of the oblique side faces outwards and a vertical positioning pin is connected inside. The panel structure of the four isosceles trapezoidal panel structure can rotate at the same angle, regardless of work Wherever personnel place the circuit board, it can be transferred to a fixed position, which improves the speed and accuracy of circuit board transfer; 4×4 concentrated openings cover the entire square panel, and its 30° oblique. The corner allows the circuit board to be finally fixed in the middle position without changing; the blessing force of the capture splint 22 covers the copper foil with the worst force 50 N to the copper foil with the strongest force 980M (existing copper foil The maximum tension that can withstand is 50 kg), it can fix copper foil of different materials and strengths, and pull it into a suitable shape to improve the accuracy of the test and ensure that the coverage area is more comprehensive; a right triangle with a top angle of 15° One side of the long right-angle side is on the horizontal plane, and the end with a top angle of 15° can shovel the circuit board up and let it be in a suspended state to ensure the accuracy of the force point; the square card slot with a depth of 5 cm can penetrate deep into the circuit The two sides of the top corner of the board can be combined with the angled sheet 300 to form a three-point fixing method for one corner, and the fixed state is more stable. The trapezoidal surface above the square card slot can extend three vertical positioning pins. When the circuit board is tested, whether the angle between the two places is 90°, to ensure that the tension of the circuit board is controlled at an excellent threshold, and it is neither concave nor convex.

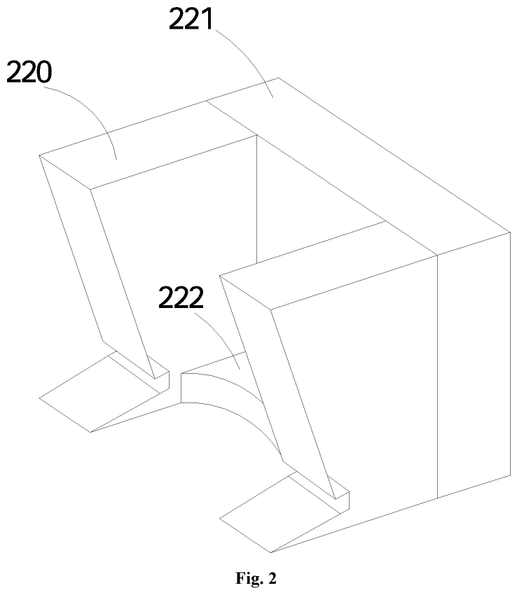

As shown in FIG. 2, the inner nails of the two side lifting plates 220 are connected with a corner fixing clip 222, and a section of the corner fixing clip 222 facing the outside is arc-shaped, and the arc-shaped corners The corner fixing clip 222 is matched with the top corner of the convex circuit board, so that the top corner can be deeper into the fixed device, and even a little looseness will not cause too much error.

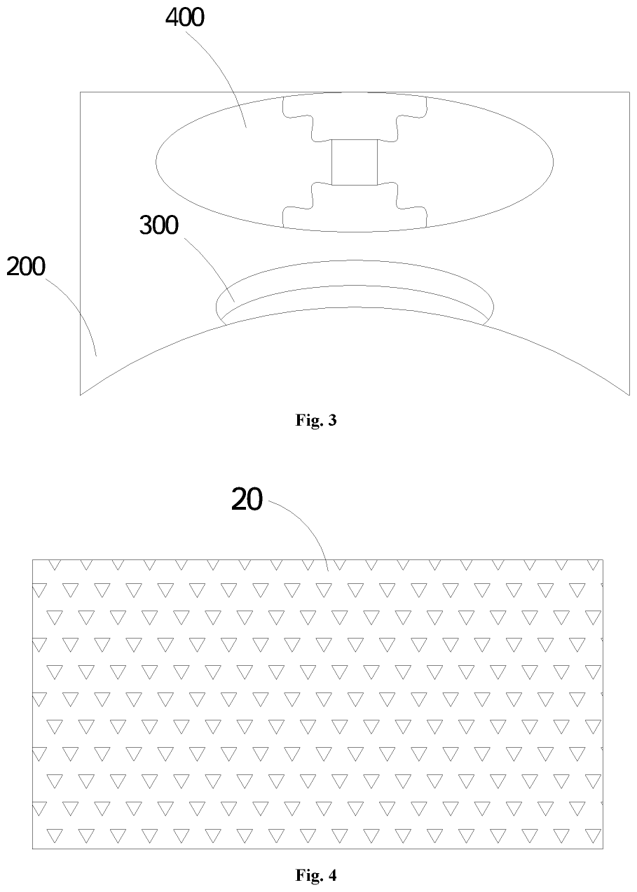

As shown in FIG. 3, the corner fixing clip 222 includes a clamping concave plate 200 connected between the two side lifting plates 220, and an electromagnetic wheel 400 is connected to the center of the clamping concave plate 200, The electromagnetic wheel 400 itself is magnetic, and there is a supercharger inside it. When the resistance is unchanged, increasing the overall voltage will increase the current and increase the magnetic force of the electromagnetic wheel 400. The electromagnetic wheel 400 can be placed on the magnetic plate 23. According to the shape of the circuit board, there are four free sliding captures. When it encounters a multi-column circuit board, the position of the column can be fixed on the four sides. The fixed test is performed on the whole board. After the position, the voltage in the electromagnetic wheel 400 increases and the current increases, which will cause the magnetism of the electromagnetic wheel 400 to become stronger, so that it is tightly attracted to the magnetic plate 23 and does not move. In the process, it can be ensured that the fixed point is not affected and moved.

As shown in FIG. 3, the inner side of the arc side end of the clamping concave plate 200 is also connected with a corner piece 300, and the inner side of the corner piece 300 has an occlusal head, which has an equilateral triangle structure. The apex is the fulcrum, and the other two vertices are used as the fulcrum to contact the circuit board. The method of three points outside and three points inside is adopted. A total of six vertices are fixed to one corner to improve the yield rate of the circuit board.

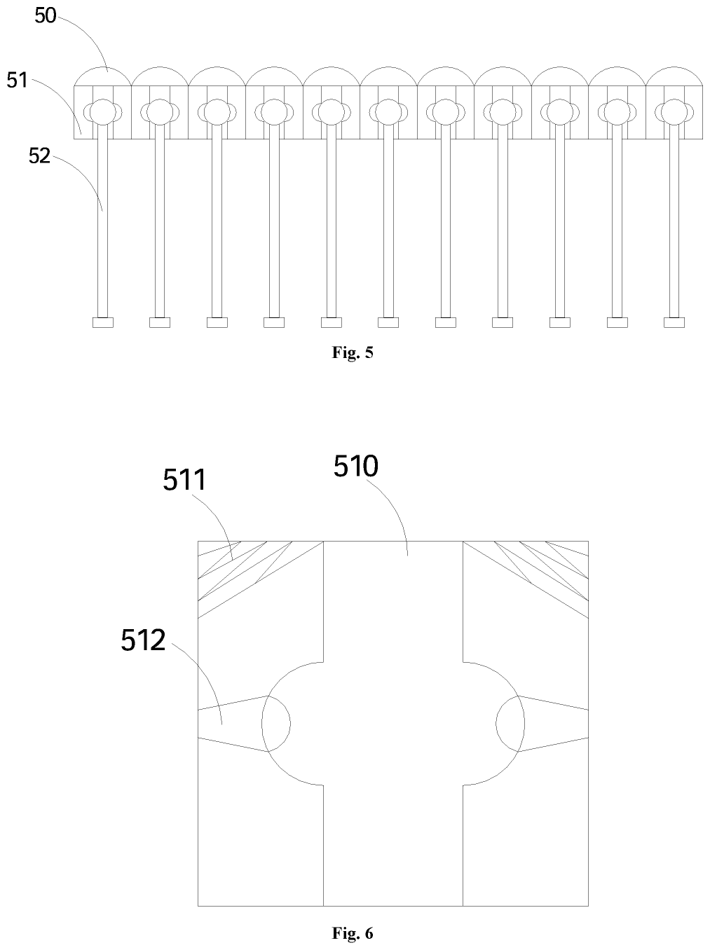

As shown in FIG. 4 to FIG. 5, the detection probe frame 20 includes a clamping portion 51 connected inside, and a probe 52 is movably connected to the bottom of the clamping portion 51, and the top of the probe 52 is movable angle in the clamping part 51 is −30°-30°, the bottom of the probe 52 is a triangle, and its three downward faces are connected with friction hair balls. The friction hair balls are circular colloids and have certain flexibility, the top of the clamping portion 51 also includes a signal lamp 50 electrically connected with the probe 52, the signal lamp 50 lights up green when the power is on and transmits current, and there is no brightness when the power is off. Gray, when there is no current when contacting the circuit, it is displayed in red. The active area formed by the movable angle of the probe 52 is the distance between the two probes 52, so that it can cover the line when correcting the dead pixels. The whole area of, can make the entire circuit penetrate; the friction ball on three sides can ensure that one side will not rub against the oxidation point or the other side of the dirt can also have overlapping areas, and there is no dead corner for correction and removal; The three states of the indicating lamp 50 can clearly reflect the normal point, the fault point, and the wireless way point. The number of defective points on the circuit board can be judged simply by reading the meter.

As shown in FIG. 4 to FIG. 5, the density of probes distributed on the lower surface of the detection probe 20 is 18×11, and a total of 198 probes 52 can cover all the points on the flexible circuit board. The needle 52 corresponds to the number and position of the clamping part 51 and the indicating lamp 50. The 198 probes can cover 90% of the circuit board points. When encountering complex double-sided or even multi-sided. the circuit board can detect points on multiple surfaces by means of sub-area detection.

As shown in FIG. 5 to FIG. 6, the clamping portion 51 includes a clamping cavity 510 connected inside. The upper left corner and the upper right corner of the clamping cavity 510 are respectively connected with a dismounting adjustment arm 511, so the disassembly adjusting arm 511 can rotate 30° left and right with the inner vertex as the axis. The left and right ends of the inner side of the clamping cavity 510 also include two sets of oscillating heads 512. The oscillating head 512 has an oscillator inside which can be Controlling it to perform periodic reciprocating movement, the disassembly adjusting arm 511 can open the clamping cavity 510, and the clamping cavity 510 can be disassembled. When simple circuit boards are frequently tested, the clamping cavity 510 and the probe 52 in the area that do not need to be detected are disassembled, which is more energy-saving. The oscillating head 512 is connected with an oscillating circuit. The oscillating circuit is an existing technology. It is not described in detail here. Periodically oscillate the probe 52 to swing it left and right, so that the probe 52 can swing quickly, and each probe 52 swings at the same frequency and angle, ensuring that each position is corrected while not interacting with each other. Collision and conflict improve the accuracy and order of correction.

The method for the test device as described above comprises the following steps.

S1: transmission: providing a processed flexible circuit board without components soldered thereon onto a magnetic board, no need to specify the position, the magnetic board attracts the flexible circuit board to a middle square panel, and central ports in the square panel allows the flexible circuit board to move to the middle position.

S2: positioning: moving the electromagnetic wheel to four corners of the flexible circuit board; if a pattern of the circuit board has multiple branches, a wire board is divided into multiple tests; the lifting board clamps the two sides, and the corner piece clamps the top corner and allows the electromagnetic wheel to expand outward, so that the flexible circuit board is tightened;

S3: judgment: moving the probe down to the copper foil of the flexible circuit board; at this time, the normal copper foil point is formed with the probe and the indicator light; when the circuit is turned on, the indicator light will light up; when the abnormal copper foil is in contact with the probe and the indicator light, the indicator light; no normal current is received, but the pressure signal feedback of the probe touching the copper foil is obtained, and the red fault light is lit up immediately, which is the fault point;

S4: correction: for the location of the fault point, activating the oscillating head to periodically impact the probe, so that the friction hair ball at the bottom of the probe; rubbing the circuit on the copper foil, wipe away the excess oxidation and possible contamination of foreign objects, and stimulating the circuit to make it through the test as much as possible.

S5: marking: when all the indicator lights in a flexible circuit board are all lit green, the entire circuit is on, and the marking mechanism in the detection probe is activated to mark the detection probe; the marked flexible circuit board is a qualified circuit board, and the rest without being marked are unqualified.

The above are only the preferred embodiments of the present disclosure and are not used to limit the present disclosure. For those skilled in the art, the present disclosure can have various modifications and changes. Any modification, equivalent replacement, improvement, etc. made within the spirit and principle of the present disclosure shall be included in the protection scope of the present disclosure.

What is claimed is:

1. A test device for roll-to-roll board of flexible circuit boards, comprising a detection probe frame (20), front and rear ends of the detection probe frame (20) being connected to a sliding frame (21), and a bottom of the sliding frame (21) being connected to a magnetic plate (23);
wherein the magnetic plate (23) is consisted of a square panel in the middle and four isosceles trapezoidal panels in upright direction; the four isosceles trapezoidal panels is movable and is capable of being rotated towards the square panel;
a bottom of the square panel is provided with 4×4 centralized ports, the angle between the centralized port and a vertical line of the panel is 30°;
the upper surface of the magnetic plate (23) is provided with four catching splints (22), the catching splint (22) is movable on the magnetic plate (23), and there is a magnetic relationship between the catching splint and the magnetic plate;
a pulling force of the catching splint (22) is 50 N-980 N; the catching splint (22) comprises a buckle frame (221); the buckle frame (221) is welded with two side lifting plates (220); a bottom of the side lifting plate (220) is a right-angled triangle with an apex angle of 15°, and a square slot is connected to the side lifting plate (220); a depth of the square slot is 5 cm; a top of the square slot is a right-angle trapezoid; one side of an oblique side of side lifting plate faces outward and a vertical positioning pin is connected inside.

2. The test device according to claim 1, wherein inner side nails of the two side lifting plates (220) are connected to corner fixing clips (222); a section of the corner fixing clip (222) facing the outside is arc-shaped.

3. The test device according to claim 2, wherein the corner fixing clip (222) comprises a clamping concave plate connected between the two side lifting plates (220); an inner center of the clamping concave plate (200) is connected to an electromagnetic wheel (400); the electromagnetic wheel (400) is magnetic, and a supercharger is located within the electromagnetic; increasing the overall voltage in the case of constant resistance, the current is increased and, therefore, the magnetic force of the electromagnetic wheel (400) is increased.

4. The test device according to claim 3, wherein an inner side of one end of the arc edge of the clamping concave plate (200) is also connected to a corner piece (300); the inner side of the corner piece (300) has an occlusal head, the occlusal head is an equilateral triangle structure, one of the vertices being used as the fulcrum, and the other two vertices being used as the fulcrum to contact the circuit board.

5. The test device according to claim 1, wherein the detection probe (20) comprises a clamping portion (51) connected therein; a probe (52) is movably connected to a bottom of the clamping portion (51), and a movable angle of the top of the probe (52) in the clamping portion (51) is −30° to 30°; a bottom part of the probe (52) is a triangular body, and three downward faces of the probe (52) are all connected with friction hair balls; the friction hair balls are round colloids and have certain flexibility; the top of the clamping portion (51) also comprises an indicator light (50) electrically connected to the probe (52); the indicator light (50) turns green when the indicator light is energized and transmits current; the indicator light (50) turns gray when the indicator light (50) loses power; the indicator light (50) turns red when the indicator light (50) contacts the circuit and there is no current.

6. The test device according to claim 1, wherein the density of the probes (52) distributed on the lower surface of the detection probe (20) is 18×11; a total of 198 probes (52) cover all the points on the flexible circuit board; the probes (52) correspond to the number and positions of the clamping portion (51) and the indicator light (50) one by one.

7. The test device according to claim 5, wherein the clamping portion (51) comprises a clamping cavity (510) connected therein; an upper left corner and an upper right corner of the clamping cavity (510) are respectively connected with a disassembly adjusting arm (511); the disassembly adjusting arm (511) is capable of being rotated 30° left and right with the inner vertex as the axis, so the left and right ends of the inner side of the clamping cavity (510) also comprise two sets of oscillating heads (512); the oscillating heads (512) have an oscillator inside which can be controlled to perform periodic reciprocating movements; the disassembly adjusting arm (511) is capable of opening the clamping cavity (510).

8. A test method for the test device according to claim 1, comprising the following steps:
S1: transmission: providing a processed flexible circuit board without components soldered thereon onto a magnetic board (23), no need to specify the position, the magnetic board (23) attracts the flexible circuit board to a middle square panel, and central ports in the square panel allows the flexible circuit board to move to the middle position.
S2: positioning: moving the electromagnetic wheel (400) to four corners of the flexible circuit board; if a pattern of the circuit board has multiple branches, a wire board is divided into multiple tests; the lifting board (220) clamps the two sides, and the corner piece (300) clamps the top corner and allows the electromagnetic wheel (400) to expand outward, so that the flexible circuit board is tightened;
S3: judgment: moving the probe (52) down to the copper foil of the flexible circuit board; at this time, the normal copper foil point is formed with the probe (52) and the indicator light (50); when the circuit is turned on, the indicator light (50) will light up; when the abnormal copper foil is in contact with the probe (52) and the indicator light (50), the indicator light (50; no normal current is received, but the pressure signal feedback of the probe (52) touching the copper foil is obtained, and the red fault light is lit up immediately, which is the fault point;
S4: correction: for the location of the fault point, activating the oscillating head (512) to periodically impact the probe (52), so that the friction hair ball at the bottom of the probe (52); rubbing the circuit on the copper foil, wipe away the excess oxidation and possible contamination of foreign objects, and stimulating the circuit to make it through the test as much as possible.
S5: marking: when all the indicator lights (50) in a flexible circuit board are all lit green, the entire circuit is on, and the marking mechanism in the detection probe (20) is activated to mark the detection probe; the marked flexible circuit board is a qualified circuit board, and the rest without being marked are unqualified.
